(19) United States
(12) Patent Application Publication
(10) Pub. No.: US 2026/0146806 A1
(43) Pub. Date: May 28, 2026

(54) RADIATOR AND WIRELESS DEVICE

(71) Applicant: NEC Corporation, Tokyo (JP)

(72) Inventor: Keiichi MOTOI, Tokyo (JP)

(73) Assignee: NEC Corporation, Tokyo (JP)

(21) Appl. No.: 19/398,130

(22) Filed: Nov. 24, 2025

(30) Foreign Application Priority Data
Nov. 26, 2024 (JP) 2024-205374

(51) Int. Cl. F28F 3/04; F28D 21/00; H01Q 1/02

(52) U.S. Cl. CPC F28F 3/048; F28D 2021/0029; F28F 2215/04; H01Q 1/02

(57) ABSTRACT

A radiator includes a heat dissipation plate that supports a heat source, first heat dissipation fins disposed on the heat dissipation plate and extending in a first direction in a plane of the heat dissipation plate, and second heat dissipation fins disposed on the heat dissipation plate and extending in the first direction. The heat dissipation plate, and the first and second heat dissipation fins are made of a solid material having thermal conductivity and electrical conductivity. A heat dissipation fin structure is formed in which the first and second heat dissipation fins are arranged in a predetermined order in a second direction in the plane of the heat dissipation plate. The second heat dissipation fins are shorter in length in the first direction than the first heat dissipation fins. The first heat dissipation fins are lower in height than the second heat dissipation fins.

### INCORPORATION BY REFERENCE

This application is based upon and claims the benefit of priority from Japanese patent application No. 2024-205374, filed on Nov. 26, 2024, the disclosure of which is incorporated herein in its entirety by reference.

### TECHNICAL FIELD

The present disclosure relates to a radiator and a wireless device.

### BACKGROUND ART

In recent years, sophistication of mobile communication systems such as an increase in capacity and an increase in speed of wireless communication represented by a fifth generation mobile communication system (5th Generation) has progressed, and there is a demand for high functionality of mobile base stations such as beamforming.

As such high functionality is demanded, a wireless device is required to have high heat dissipation performance. For example, JP 6520568 B2 discloses a wireless device in which a radiator is constituted by a metal base plate disposed on the same surface as an antenna surface and a metal wall provided on the metal base plate so as to surround an antenna element.

### SUMMARY

As disclosed in JP 6520568 B2, in a case where a heat dissipation portion (heat sink) is disposed on the same surface as the antenna surface, it is necessary to provide a wall surrounding the antenna element in order to reduce an influence on antenna characteristics, and there is a problem that a degree of freedom in designing the radiator is reduced.

An example object of the present disclosure is to provide a radiator and a wireless device for solving such a problem.

A radiator according to an example aspect of the present disclosure includes
a heat dissipation plate that supports a heat source,
first heat dissipation fins disposed on the heat dissipation plate and extending in a first direction in a plane of the heat dissipation plate, and
second heat dissipation fins disposed on the heat dissipation plate and extending in the first direction, wherein
the heat dissipation plate, the first heat dissipation fins, and the second heat dissipation fins are made of a solid material having thermal conductivity and electrical conductivity,
a heat dissipation fin structure is formed in which the first heat dissipation fins and the second heat dissipation fins are arranged in a predetermined order in a second direction in the plane of the heat dissipation plate,
a fin length of the second heat dissipation fins in the first direction is shorter than a fin length of the first heat dissipation fins in the first direction, and
a fin height of the first heat dissipation fins is lower than a fin height of the second heat dissipation fins.

A wireless device according to an example aspect of the present disclosure includes
the radiator described above, and
a radiating element or a reflective element disposed inside a heat dissipation fin structure of the radiator.

According to the present disclosure, it is possible to provide a radiator capable of improving a degree of freedom in designing the radiator, and a wireless device.

### BRIEF DESCRIPTION OF DRAWINGS

FIG. 1A is a perspective view illustrating a configuration example of a radiator of the present disclosure;

FIG. 1B is a side view illustrating the configuration example of the radiator of the present disclosure;

FIG. 2 is a schematic diagram for calculating a heat dissipation fin area of the radiator of the configuration example of the present disclosure;

FIG. 3 is a perspective view of a heat dissipation structure example 1 and a diagram illustrating definitions of radio wave propagation directions;

FIG. 4A is a diagram illustrating an electromagnetic field simulation result of a frequency dispersion characteristic of the heat dissipation structure example 1;

FIG. 4B is a schematic diagram of symmetry points (points K) in a Brillouin zone of a reciprocal space;

FIG. 4C is a diagram extracting a low-frequency band including an EBG of the electromagnetic field simulation result of the frequency dispersion characteristic of the heat dissipation structure example 1;

FIG. 5A is a diagram illustrating an electromagnetic field simulation result of an S parameter S21 (transmission intensity) in a case where a radio wave propagates in a direction (y-axis) perpendicular to a straight fin in the heat dissipation structure example 1;

FIG. 5B is a diagram illustrating an electromagnetic field simulation result of the S parameter S21 (transmission intensity) in a case where a radio wave propagates in a longitudinal direction (x-axis) of the straight fin in the heat dissipation structure example 1;

FIG. 6 is a perspective view of a heat dissipation structure example 2 and a diagram illustrating definitions of the radio wave propagation directions;

FIG. 7 is a diagram illustrating electromagnetic field simulation results of surface wave propagation in a fin longitudinal direction in a heat dissipation fin structure of the heat dissipation structure example 2;

FIG. 8 is a perspective view of a heat dissipation structure example 3 and a diagram illustrating definitions of the radio wave propagation directions;

FIG. 9 is a diagram illustrating electromagnetic field simulation results of surface wave propagation in the fin longitudinal direction in the heat dissipation fin structure of the heat dissipation structure example 3;

FIG. 10 is a diagram illustrating electromagnetic field simulation results of frequency dispersion characteristics in a case where a fin height of first heat dissipation fins is changed and a fin height of second heat dissipation fins is fixed in the configuration example of the radiator of the present disclosure;

FIG. 11 is a perspective view illustrating the configuration example of the radiator of the present disclosure and a diagram illustrating definitions of the radio wave propagation directions;

FIG. 12 is a diagram illustrating electromagnetic field simulation results of surface wave propagation in the fin longitudinal direction in the heat dissipation fin structure exemplified in the present disclosure;

FIG. 13A is a diagram illustrating an electromagnetic field simulation result of the S parameter S21 (transmission intensity) in a case where a radio wave propagates in a direction (y-axis) perpendicular to the heat dissipation fin in the configuration example of the radiator of the present disclosure;

FIG. 13B is a diagram illustrating an electromagnetic field simulation result of the S parameter S21 (transmission intensity) in a case where a radio wave propagates in a longitudinal direction (x-axis) of the heat dissipation fin in the configuration example of the radiator of the present disclosure;

FIG. 14 is a diagram illustrating a simulation result of an electric field vector in a case where fin heights of straight fins and rectangular fins are equal;

FIG. 15 is a diagram illustrating a simulation result of the electric field vector in a case where the fin height of the straight fins is lower than the fin height of the rectangular fins;

FIG. 16A is an analysis model diagram by general straight fins in a thermal fluid simulation;

FIG. 16B is an analysis model diagram by general rectangular fins in the thermal fluid simulation;

FIG. 16C is an analysis model diagram by the heat dissipation fin structure exemplified in the present disclosure in the thermal fluid simulation;

FIG. 17A is a steady temperature distribution diagram of a heat dissipation structure surface by the general straight fins under a natural convection condition, which is obtained by the thermal fluid simulation;

FIG. 17B is a steady temperature distribution diagram of a heat dissipation structure surface by the general rectangular fins under the natural convection condition, which is obtained by the thermal fluid simulation;

FIG. 17C is a steady temperature distribution diagram of a heat dissipation structure surface by the heat dissipation fin structure exemplified in the present disclosure under the natural convection condition, which is obtained by the thermal fluid simulation;

FIG. 18A is a graph comparing steady maximum temperatures of an internal heat source according to respective heat dissipation fin shapes under the natural convection condition, which is obtained by the thermal fluid simulation;

FIG. 18B is a graph comparing steady maximum temperatures of the heat dissipation structure surface according to the respective heat dissipation fin shapes under the natural convection condition, which is obtained by the thermal fluid simulation;

FIG. 19 is a configuration diagram illustrating a Vivaldi antenna element;

FIG. 20 is a schematic diagram illustrating a surface impedance at a fin end surface of a heat dissipation fin structure having EBG characteristics;

FIG. 21A is a perspective view illustrating a configuration example of an array antenna device of the present disclosure;

FIG. 21B is a side view illustrating the configuration example of the array antenna device of the present disclosure;

FIG. 21C is a different side view illustrating the configuration example of the array antenna device of the present disclosure;

FIG. 21D is a plan view illustrating the configuration example of the array antenna device of the present disclosure;

FIG. 22A is a diagram illustrating a radiation pattern at 3.4 GHz during an antenna element operation of 3×2 elements of the array antenna device including a general heat dissipation fin;

FIG. 22B is a diagram illustrating a radiation pattern at 3.7 GHz during the antenna element operation of 3×2 elements of the array antenna device including the general heat dissipation fin;

FIG. 22C is a diagram illustrating a radiation pattern at 4.0 GHz during the antenna element operation of 3×2 elements of the array antenna device including the general heat dissipation fin;

FIG. 23A is a diagram illustrating a radiation pattern at 3.4 GHz during an antenna element operation of 3×2 elements of the array antenna device having the heat dissipation fin structure exemplified in the present disclosure;

FIG. 23B is a diagram illustrating a radiation pattern at 3.7 GHz during the antenna element operation of 3×2 elements of the array antenna device having the heat dissipation fin structure exemplified in the present disclosure;

FIG. 23C is a diagram illustrating a radiation pattern at 4.0 GHz during the antenna element operation of 3×2 elements of the array antenna device having the heat dissipation fin structure exemplified in the present disclosure;

FIG. 24 is a diagram schematically illustrating a flow of a refrigerant inside general rectangular fins; and

FIG. 25 is a diagram schematically illustrating a flow of the refrigerant inside the heat dissipation fin of the configuration example of the present disclosure.

### EXAMPLE EMBODIMENT

Hereinafter, example embodiments will be described with reference to the drawings. Since the drawings are simplified, the technical scope of the example embodiments should not be narrowly interpreted based on the description of the drawings. The same elements are denoted by the same reference numerals, and redundant description will be omitted.

In the following example embodiments, if necessary for convenience, the description will be divided into a plurality of sections or example embodiments. However, unless otherwise specified, they are not unrelated to each other, and one is in a relationship of some or all modified examples, application examples, detailed descriptions, supplementary descriptions, and the like of the other.

In the following example embodiments, in a case of referring to the number of elements and the like (including number, numerical value, amount, range, and the like), the number is not limited to a specific number unless otherwise specified or clearly limited to the specific number in principle, and the number may be equal to or more than the specific number or may be equal to or less than the specific number.

Furthermore, in the following example embodiments, the components are not necessarily essential unless otherwise specified or considered to be obviously essential in principle.

Similarly, in the following example embodiments, in a case of referring to the shape, positional relationship, etc. of components, etc., it is intended to include things that are substantially similar or approximate to those shapes, etc., unless otherwise specified or considered to be clearly different in principle. The same applies to the above numbers (including number, numerical value, amount, range, and the like).

### First Example Embodiment

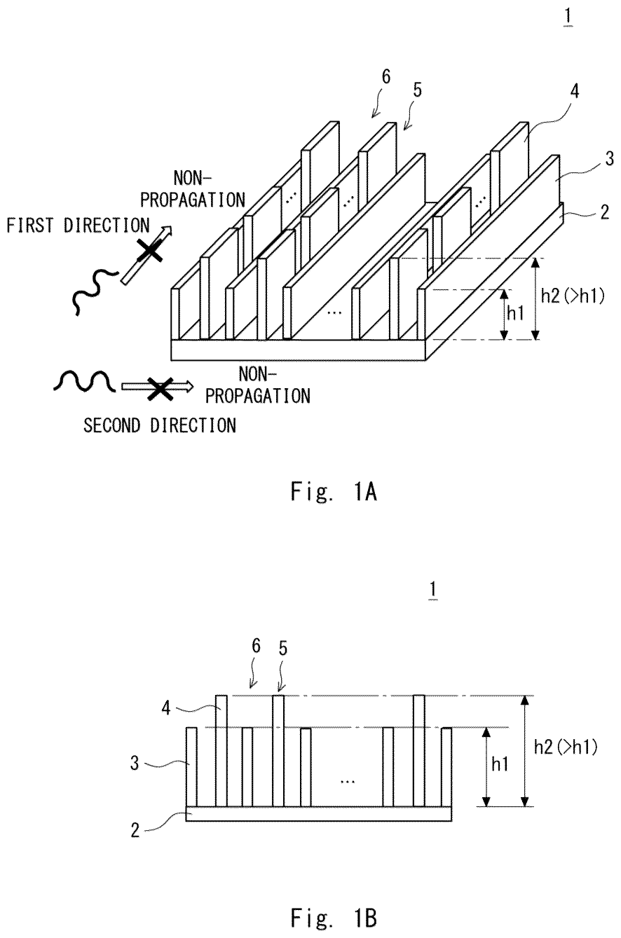

The present example embodiment will be described with reference to FIGS. 1A to 18B. FIG. 1A is a perspective view illustrating a configuration example of a radiator of the present disclosure, and FIG. 1B is a side view illustrating the configuration example of the radiator of the present disclosure. As illustrated in FIGS. 1A and 1B, a radiator 1 of the present example embodiment includes a heat dissipation plate 2, first heat dissipation fins 3, and second heat dissipation fins 4.

As illustrated in FIGS. 1A and 1B, the heat dissipation plate 2 has a flat plate shape. The heat dissipation plate 2 supports a heat source as described later. The first heat dissipation fins 3 are made of a solid material having high thermal conductivity and electrical conductivity. The first heat dissipation fins 3 are disposed on the heat dissipation plate 2.

As illustrated in FIGS. 1A and 1B, the first heat dissipation fins 3 extend in a first direction in a plane of the heat dissipation plate 2, and have a continuous shape in the first direction. Here, in the present disclosure, fins continuous in the first direction such as the first heat dissipation fins 3 may collectively be referred to as straight fins. Here, the first direction and a second direction are preferably orthogonal to each other.

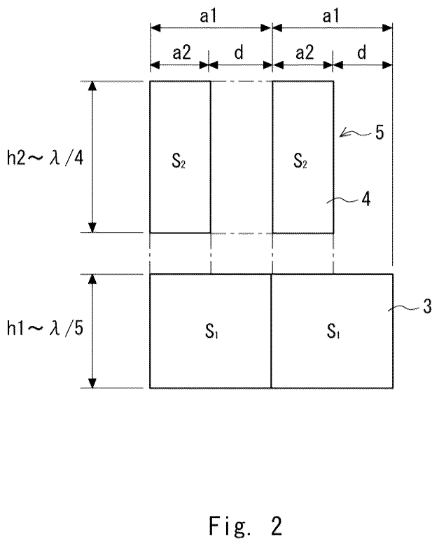

The second heat dissipation fins 4 are made of a solid material having high thermal conductivity and electrical conductivity. As illustrated in FIGS. 1A and 1B, the second heat dissipation fins 4 are disposed on the heat dissipation plate 2 and extend in the first direction. A fin length L2 (fin width a2 in FIG. 2) of the second heat dissipation fins 4 in the first direction is shorter than a fin length L1 (fin width a1 in FIG. 2) of the first heat dissipation fins 3 in the first direction.

For example, as illustrated in FIGS. 1A and 1B, the second heat dissipation fins 4 have a substantially rectangular shape as viewed from the second direction. As illustrated in FIG. 1B, a fin height h2 of the second heat dissipation fins 4 is higher than a fin height h1 of the first heat dissipation fins 3.

As illustrated in FIG. 1A, the second heat dissipation fins 4 constitute a heat dissipation fin row 5 in which the second heat dissipation fins 4 are discretely and periodically arrayed at a pitch p(=a2+d, d: fin distance) in the first direction on the heat dissipation plate 2.

A heat dissipation fin structure 6 is formed in which the first heat dissipation fins 3 and the second heat dissipation fins 4 are alternately arranged in the second direction. Here, in the present disclosure, rectangular fins discretely arrayed in the first direction such as the second heat dissipation fins 4 may collectively be referred to as rectangular fins.

At this time, the fin height h1 of first heat dissipation fins 3 and the fin height h2 of the second heat dissipation fins 4 are adjusted in such a way that the heat dissipation fin structure 6 as a whole exhibits an electromagnetic band gap (EBG) for a predetermined operation frequency f.

Here, as one numerical example of the fin heights of the first heat dissipation fins 3 and the second heat dissipation fins 4, with a wavelength corresponding to the predetermined operation frequency f as λ (=c/f, c: light speed), in a case where the fin height h1 of the first heat dissipation fins 3 is approximately λ/6 to λ/5 and the fin height h2 of the second heat dissipation fins 4 is in the vicinity of approximately λ/4, it is preferable to achieve both improvement of a heat dissipation area and the exhibition of the EBG.

FIG. 2 is a schematic diagram for calculating a heat dissipation fin area of the radiator of the configuration example of the present disclosure. From FIG. 2, an area ratio S1/S2 of an area S1=h1×(a2+d)=λ/5×(a2+d) of the first heat dissipation fin 3 in a portion having the same width as the pitch p of the second heat dissipation fins 4 to an area S2=h2×a2=λ/4×a2 of the second heat dissipation fin 4 is (4/5)×(1+d/a2), and as a condition for increasing the area of the first heat dissipation fin 3 as compared with the area of the second heat dissipation fin 4, it is desirable that a2<4d, since S1/S2>1.

At this time, in order to increase the heat dissipation area ratio, a case is more preferable in which the fin distance d of the second heat dissipation fins 4 is large. That is, in the case of using the second heat dissipation fins 4 having a pin shape such as a cylinder in addition to the rectangular heat dissipation fin shape illustrated in FIGS. 1A, 1B, and 2, the increase ratio of the heat dissipation area becomes higher.

The ratios of the fin heights, the fin widths, and the fin distances between the first heat dissipation fins 3 and the second heat dissipation fins 4 may appropriately be selected in consideration of both electromagnetic characteristics and heat dissipation performance represented by a heat dissipation area.

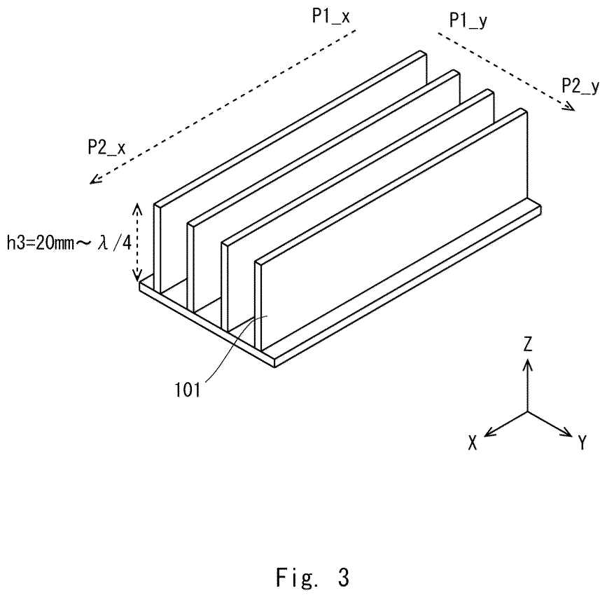

FIG. 3 is a perspective view of a heat dissipation structure example 1 including only general straight fins and a schematic view illustrating definitions of radio wave propagation directions in a fin longitudinal direction (x-axis) p_x and a fin perpendicular direction (y-axis) p_y, for comparison of effects of the configuration example of the radiator of the present disclosure.

Here, a fin height h3 of straight fins 101 is 20 mm, that is, equivalent to λ/4 in a case where a wavelength corresponding to 3.7 GHz of a main frequency of a sub 6 band is λ, and the pitch p of the straight fins 101 in the y-axis direction is 9 mm.

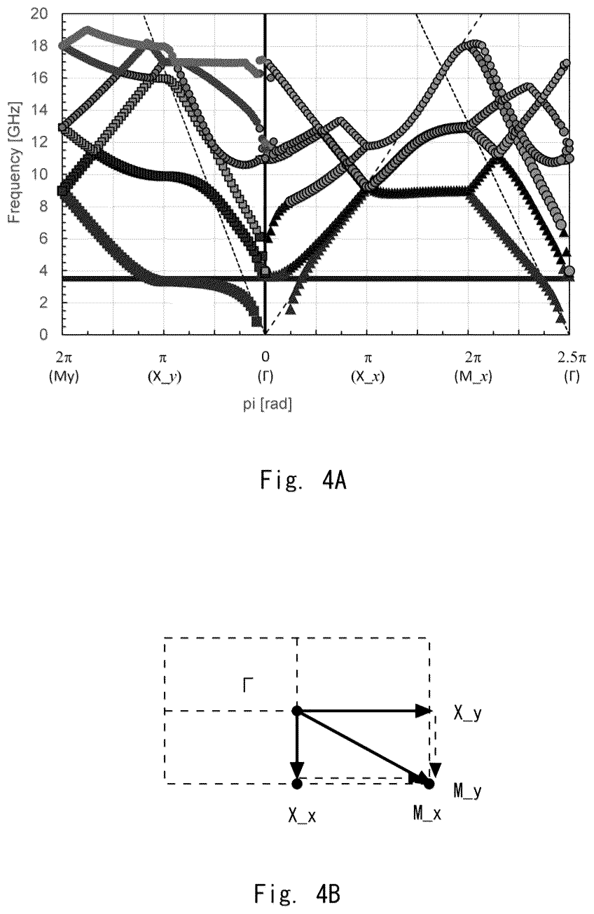

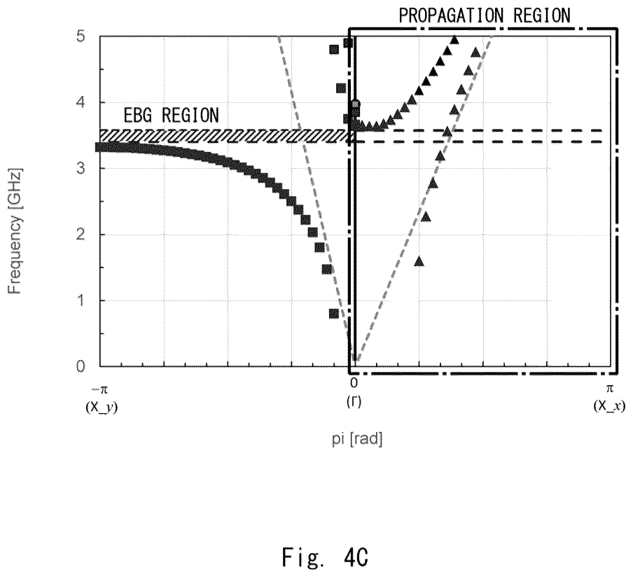

FIG. 4A is a diagram illustrating an electromagnetic field simulation result of a frequency dispersion characteristic f(k) with respect to a wave number k (∝p: phase) of the heat dissipation structure example 1 of FIG. 3, and FIG. 4B is a schematic diagram illustrating symmetry points (K points): Γ point, X_i point, and M_i point (i represents x-axis and y-axis directions) in a Brillouin zone of a reciprocal space. FIG. 4C is a diagram extracting a low-frequency band including the electromagnetic band gap (EBG) of the frequency dispersion characteristic in FIG. 4A.

As illustrated in FIG. 4C, in a +p_x direction (x-axis direction), a propagation mode exists for any wave number k, and radio wave propagation occurs in the fin longitudinal direction. On the other hand, in a +p_y direction (y-axis direction), a non-propagation region, that is, the EBG is generated in a frequency region indicated by hatching, and radio wave propagation is prevented.

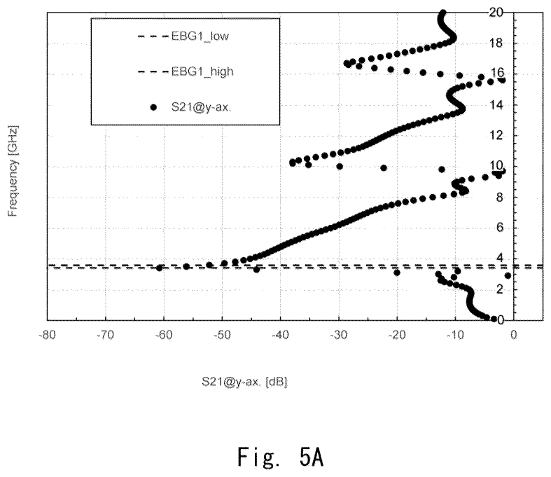

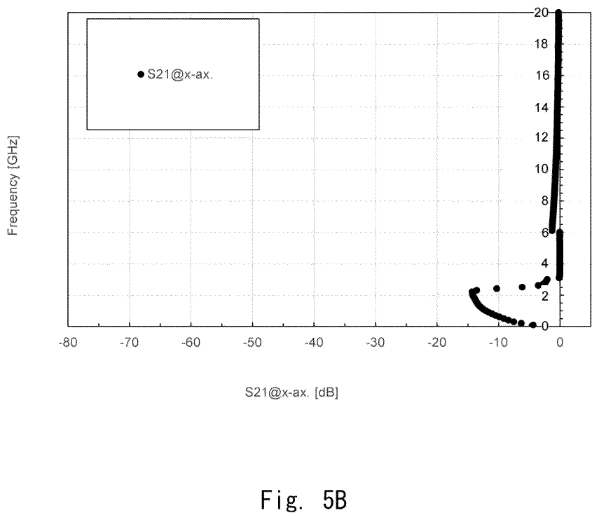

FIGS. 5A and 5B are diagrams illustrating electromagnetic field simulation results of frequency characteristics of the S parameter S21 component (transmission intensity) in the y-axis direction and the x-axis direction, respectively. In response to the result in FIG. 4C, FIG. 5A (propagation in the y-axis direction) illustrates a high attenuation characteristic of approximately S21=−60 dB in the vicinity of the EBG. On the other hand, FIG. 5B (propagation in the x-axis direction) illustrates a transmission characteristic of S21˜0 dB.

These characteristics cannot prevent radio wave propagation in a specific direction, and are particularly unsuitable for use in an array antenna device including polarized antenna elements such as orthogonal and circular polarized antenna elements having electromagnetic excitation directivity, suppression of unwanted radiation in a wireless device, and the like.

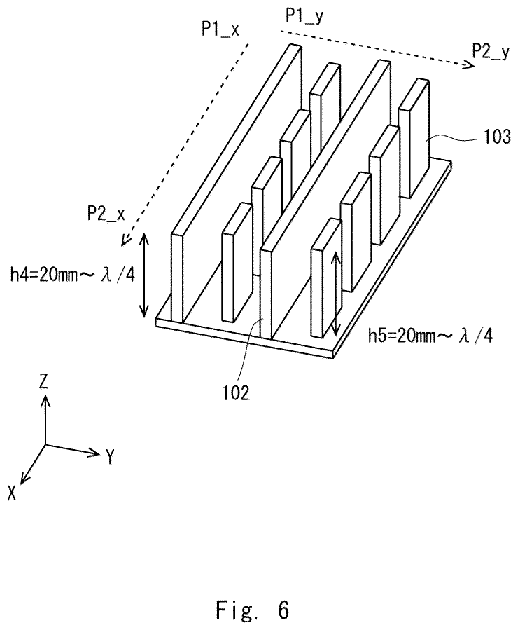

FIG. 6 is a perspective view of a heat dissipation structure example 2 including straight fins and rectangular fins, and a schematic view illustrating definitions of the radio wave propagation directions in the fin longitudinal direction (x-axis) p_x and the fin perpendicular direction (y-axis) p_y, for comparison of effects of the configuration example of the radiator of the present disclosure.

Here, a fin height h4 of straight fins 102 and a fin height h5 of rectangular fins 103 are h4=h5=20 mm, that is, both equivalent to λ/4 in a case where the wavelength corresponding to 3.7 GHz of the main frequency of the sub6 band is λ, a distance between the straight fins 102 and the rectangular fins 103 in the y-axis direction is 9 mm, the fin width a of the rectangular fins 103 is 9 mm, and the fin distance d is 9 mm (that is, the pitch p=18 mm).

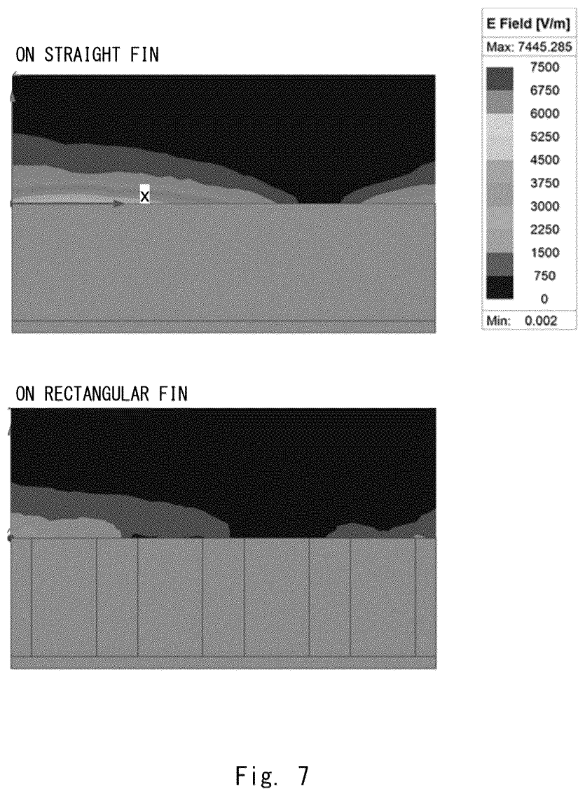

FIG. 7 is a diagram illustrating electromagnetic field simulation results of surface wave propagation in the fin longitudinal direction in the heat dissipation fin structure of the heat dissipation structure example 2 in FIG. 6. It can be seen that radio wave propagation in the fin longitudinal direction occurs on the fin end surface in both the straight fins 102 and the rectangular fins 103.

As in the heat dissipation structure example 1, these characteristics cannot prevent radio wave propagation in a specific direction, and are particularly unsuitable for use in an array antenna device including polarized antenna elements such as orthogonal and circular polarized antenna elements having electromagnetic excitation directivity, suppression of unwanted radiation in a wireless device, and the like.

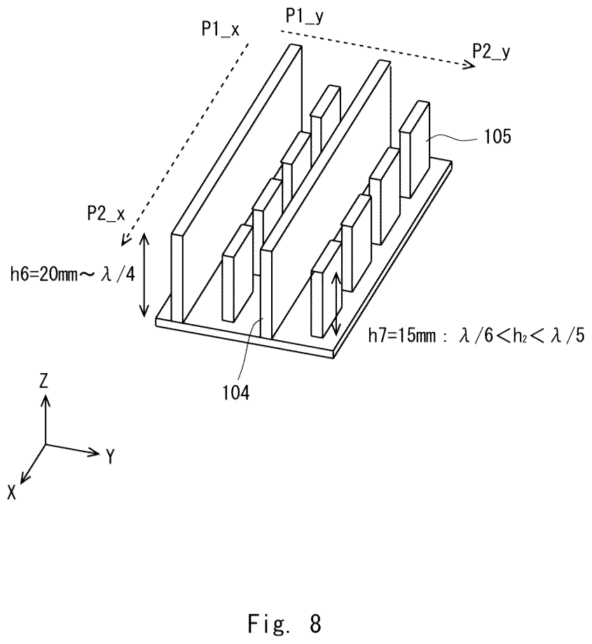

FIG. 8 is a perspective view of a heat dissipation structure example 3 including straight fins 104 and rectangular fins 105, and a schematic view illustrating definitions of the radio wave propagation directions in the fin longitudinal direction (x-axis) p_x and the fin perpendicular direction (y-axis) p_y, for comparison of effects of the configuration example of the radiator of the present disclosure.

Here, a fin height h6 of the straight fins 104 is 20 mm, a fin height h7 of the rectangular fins 105 is 15 mm, that is, in a case where the wavelength corresponding to 3.7 GHz of the main frequency of the sub6 band is λ, the fin height h6 is equivalent to λ/4 for the straight fins 104 and the fin height h7 is equivalent to λ/6<h7<λ/5 for the rectangular fins 105, and the fin height h6 of the straight fins 104 is higher than the fin height h7 of the rectangular fins 105.

In addition, a distance between the straight fins 104 and the rectangular fins 105 in the y-axis direction is 9 mm, the fin width a of the rectangular fins 105 is 9 mm, and the fin distance d is 9 mm (that is, the pitch p=18 mm).

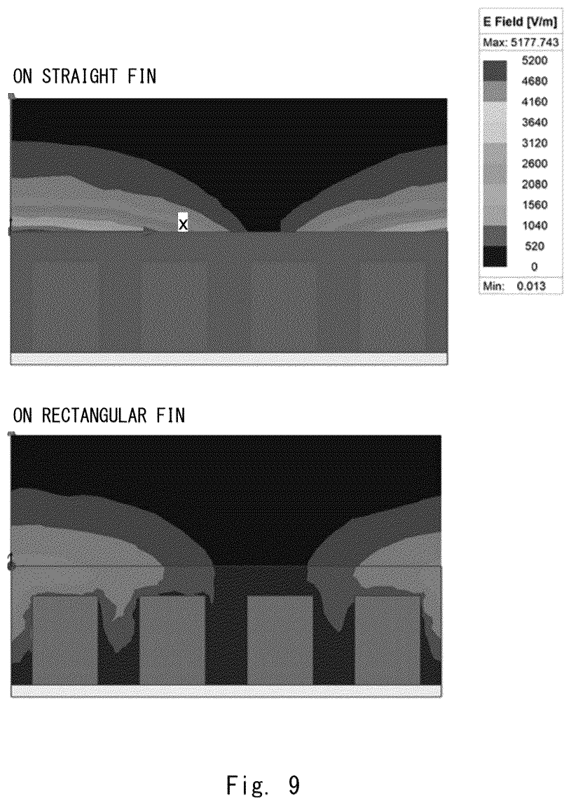

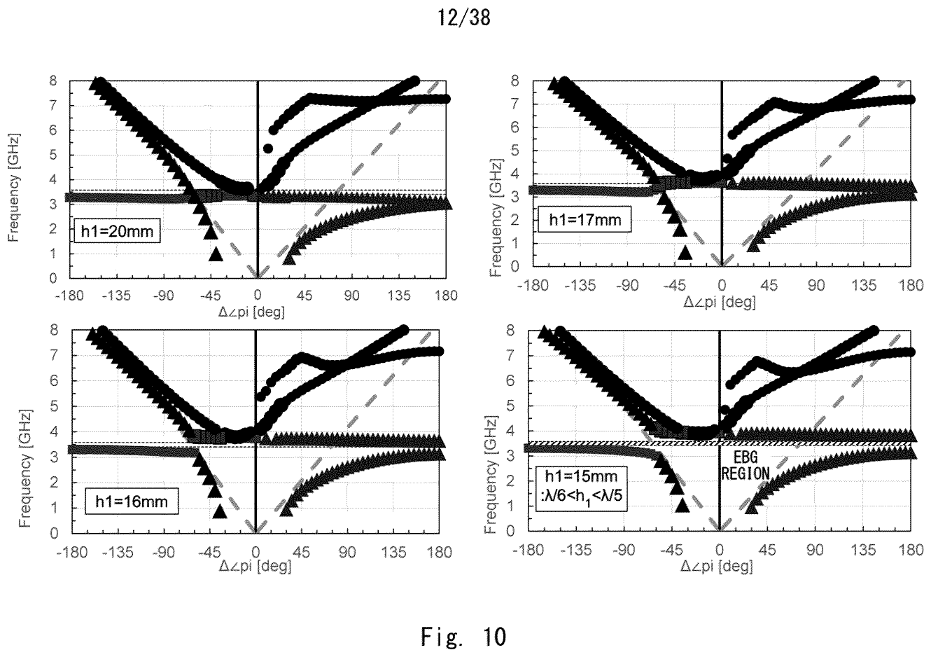

FIG. 9 is a diagram illustrating electromagnetic field simulation results of surface wave propagation in the fin longitudinal direction in the heat dissipation fin structure of the heat dissipation structure example 3 in FIG. 8. It can be seen that radio wave propagation in the fin longitudinal direction occurs on the fin end surface in both the straight fins 104 and the rectangular fins 105.

In particular, radio wave propagation occurs even in the rectangular fins 105 having a small fin height. As in the heat dissipation structure examples 1 and 2, these characteristics cannot prevent radio wave propagation in a specific direction, and are particularly unsuitable for use in an array antenna device including polarized antenna elements such as orthogonal and circular polarized antenna elements having electromagnetic excitation directivity, suppression of unwanted radiation in a wireless device, and the like.

The present disclosure has been conceived to improve a heat dissipation area while preventing the radio wave propagation as described above in any direction. FIG. 10 is a diagram illustrating electromagnetic field simulation results of frequency dispersion characteristics in a case where the fin height h1 of the first heat dissipation fins is changed to 15, 16, 17, and 20 mm and the fin height h2 of the second heat dissipation fins is fixed to 20 mm in the radiator of the configuration example of FIGS. 1a and 1b.

As illustrated in FIG. 10, in a range higher than h1=16 mm, the propagation mode exists in both the radio wave propagation directions in the fin longitudinal direction (x-axis) p_x and the fin perpendicular direction (y-axis) p_y. On the other hand, in a case where the fin height h1 of the continuous first heat dissipation fins 3 is 15 mm, that is, equivalent to λ/6<h1<λ/5, the electromagnetic band gap (EBG) occurs in the frequency region indicated by hatching, and no propagation mode occurs, making it possible to suppress radio wave propagation.

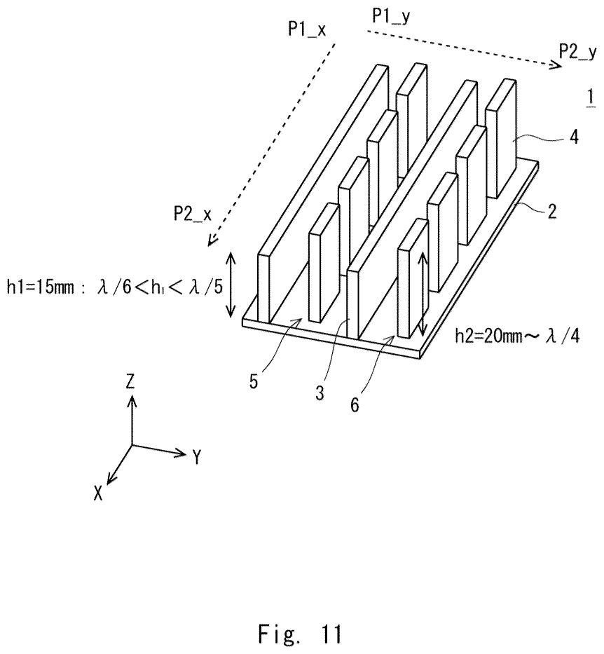

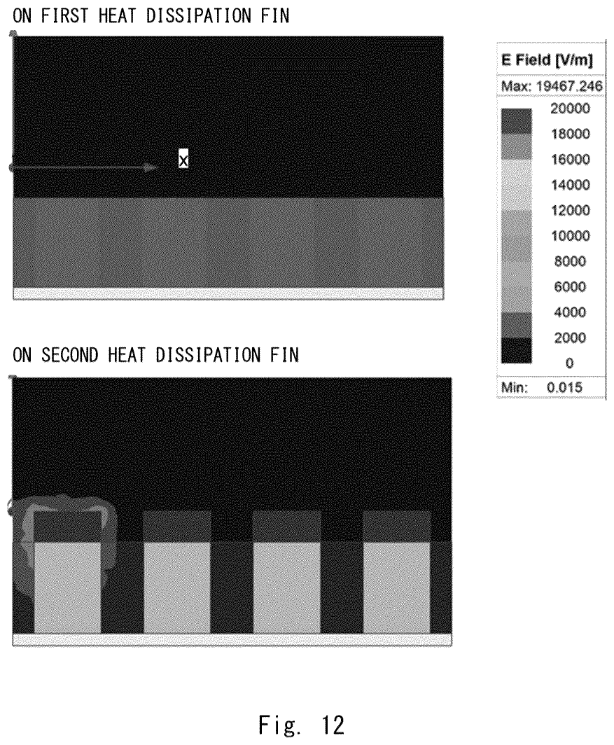

FIG. 11 is a perspective view illustrating the configuration example of the radiator of the present disclosure and a diagram illustrating definitions of the radio wave propagation directions, which are conceived by the above analysis. That is, the fin height h1 of the first heat dissipation fins 3 is 15 mm, and the fin height h2 of the second heat dissipation fins 4 is 20 mm.

FIG. 12 is a diagram illustrating electromagnetic field simulation results of surface wave propagation in the fin longitudinal direction in the heat dissipation fin structure of the radiator of the configuration example of the present disclosure in FIG. 11. It can be seen that radio wave propagation in the fin longitudinal direction is suppressed on the fin end surface in both the first heat dissipation fins 3 and the second heat dissipation fins 4.

These characteristics prevent radio wave propagation in any direction in a plane, and are particularly suitable for use in an array antenna device including polarized antenna elements such as orthogonal and circular polarized antenna elements having electromagnetic excitation directivity, suppression of unwanted radiation in a wireless device, and the like.

In addition, as in the configuration example of the radiator described above, in a case where the fin width a of the second heat dissipation fins 4 is 9 mm and the fin distance d is 9 mm (that is, the pitch p=18 mm), the heat dissipation area ratio S1/S2 is increased 4/3 times, which contributes to improvement of heat dissipation characteristics.

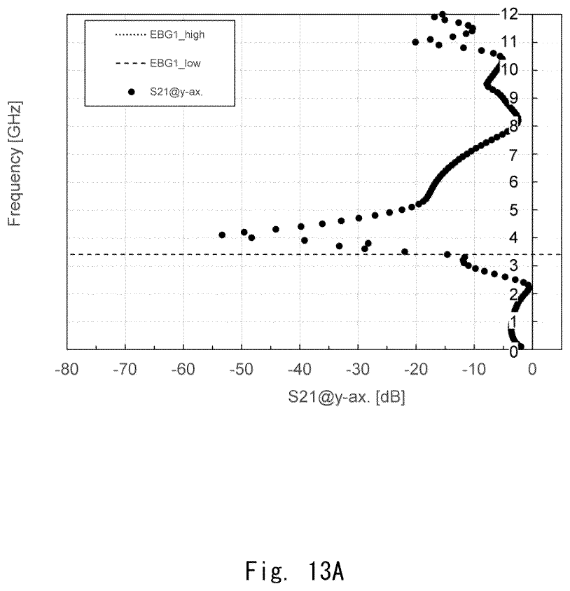

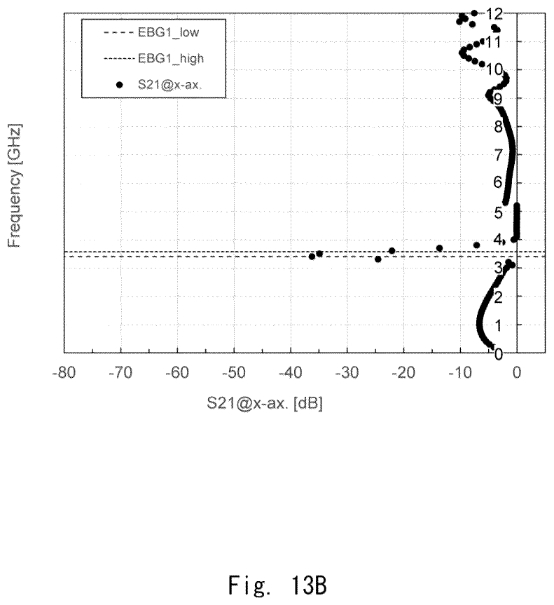

FIGS. 13A and 13B are diagrams illustrating electromagnetic field simulation results of frequency characteristics of the S parameter S21 component (transmission intensity) in the y-axis direction and the x-axis direction, respectively, of the radiator of the configuration example of the present disclosure in FIG. 11.

In response to EBG characteristics at the fin height h1=15 mm of the first heat dissipation fins 3 in FIG. 10 and the attenuation of the radio wave propagation in FIG. 12, S21 exhibits a high attenuation characteristic in the vicinity of the EBG in both directions of FIG. 13A (propagation in the y-axis direction) and FIG. 13B (propagation in the x-axis direction).

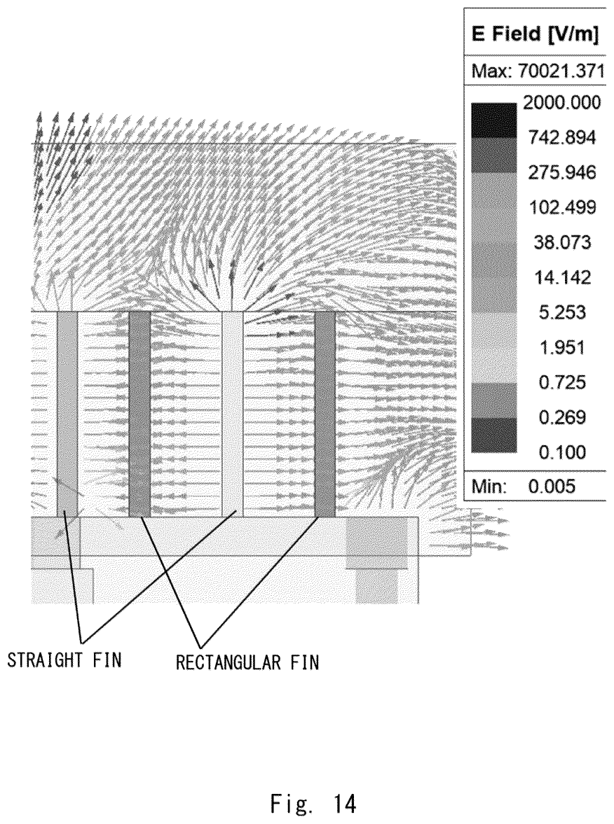

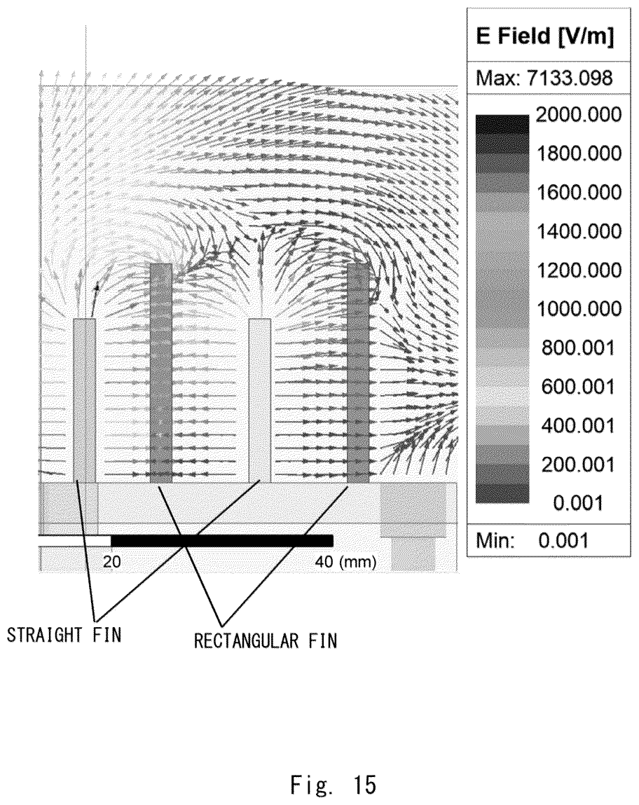

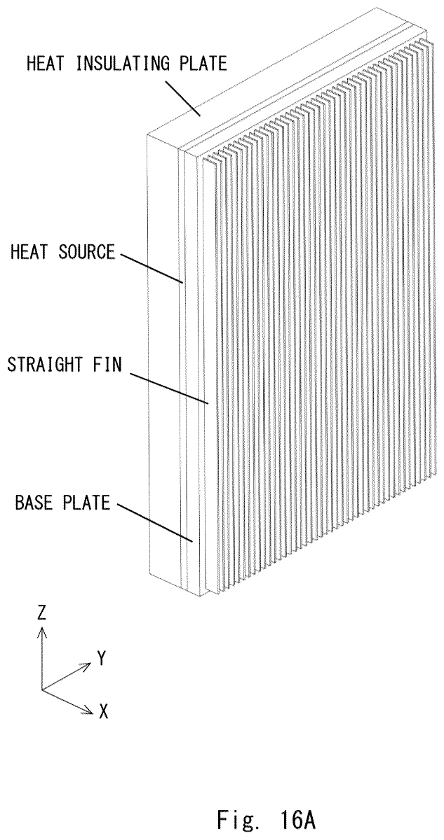

FIG. 14 is a diagram illustrating a simulation result of an electric field vector in a case where fin heights of straight fins and rectangular fins are equal. FIG. 15 is a diagram illustrating a simulation result of the electric field vector in a case where the fin height of the rectangular fins is higher than the fin height of the straight fins.

Observing a behavior of an electric field around the fins in the simulation of the electric field vector, as illustrated in FIG. 15, in a case where the straight fins are low, strong capacitive coupling occurs between adjacent rectangular fins, the capacitive coupling is particularly strong between fin tips, and a situation occurs in which the electric field concentrates on the tips of the straight fins.

From this result, as illustrated in FIGS. 14 and 15, it is presumed that electromagnetic energy is once absorbed by the rectangular fins that exert an effect of suppressing the EBG effect and the suppression of radio wave propagation in a single heat dissipation fin row via capacitive coupling, and the EBG effect and the suppression of radio wave propagation in the rectangular fins becomes dominant.

Therefore, in the case where the fin height h2 of the second heat dissipation fins 4 is higher than the fin height h1 of the first heat dissipation fins 3 as in the present example embodiment, it is presumed that the electric field can be confined in the second heat dissipation fins 4 adjacent in the y-axis direction and the effect of suppressing the EBG effect and the suppression of radio wave propagation is high.

In addition, the fin distance in the y-axis direction between the first heat dissipation fins 3 and the second heat dissipation fins 4 is preferably less than the fin height h1 of the first heat dissipation fins 3 in such a way that coupling easily occurs between the first heat dissipation fins 3 and the second heat dissipation fins 4.

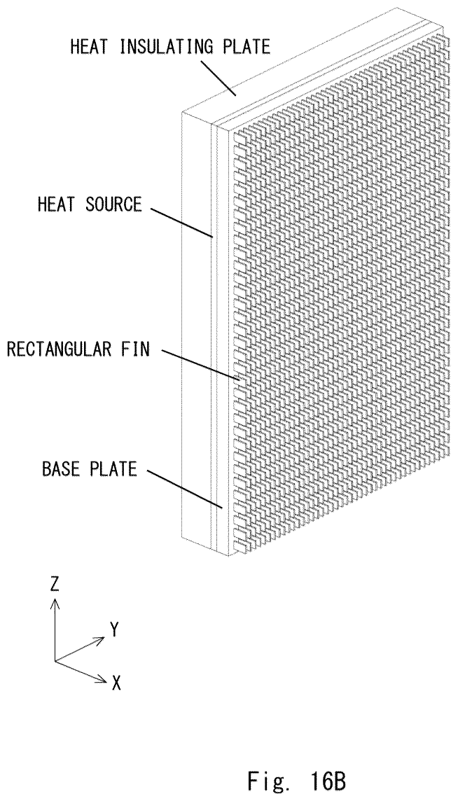

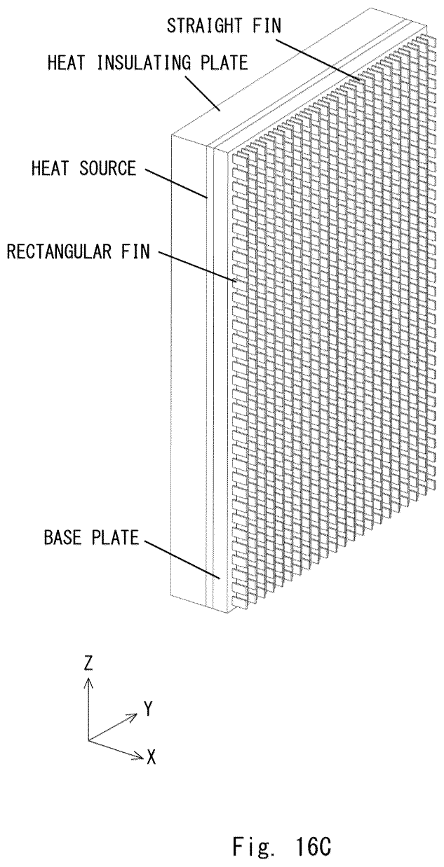

For verification of the heat dissipation characteristics of the configuration example of the radiator of the present disclosure, FIGS. 16A, 16B, and 16C respectively illustrate analysis models of a thermal fluid analysis simulation of a heat dissipation structure with only general continuous straight fins (fin height: 20 mm), a heat dissipation structure with only general discrete rectangular fins (fin height: 20 mm), and a heat dissipation structure in which straight fins (fin height: 15 mm) that are the first heat dissipation fins 3 and rectangular fins (fin height: 20 mm) that are the second heat dissipation fins 4 of the configuration example of the present disclosure are alternately arranged.

Here, a surface area of a base plate (heat dissipation plate) of the heat dissipation fins, a heat source, and a rear heat insulating plate is set to 400 mm×600 mm, a base plate thickness is set to 20 mm, a heat source thickness is set to 10 mm, a heat insulating plate thickness is set to 50 mm, each thermal conductivity is set to 140 W/(m·K) for the base plate and the fins and 0.3 W/(m·K) for the heat insulating plate, the calorific value of the heat source is set to 500 W, and an environmental temperature is set to 50° C.

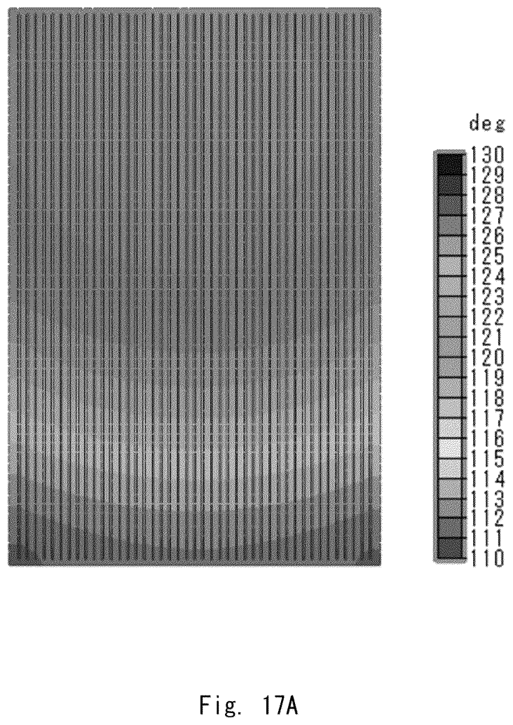

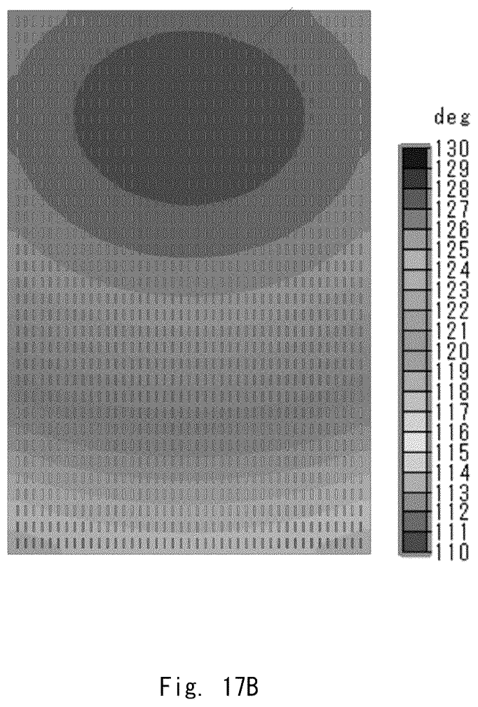

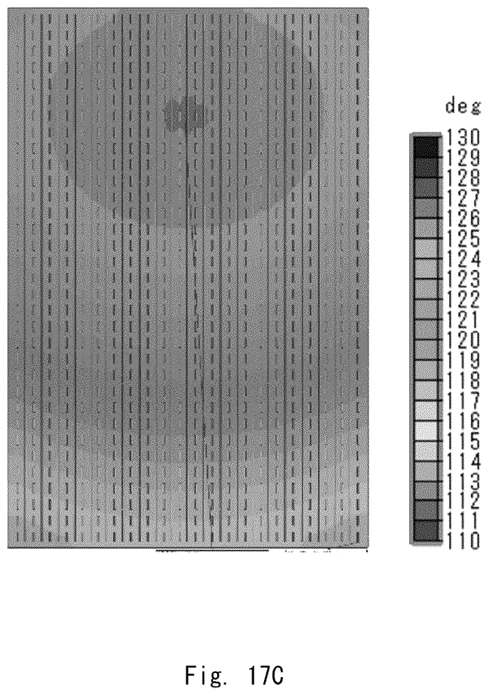

FIGS. 17A, 17B, and 17C are steady temperature distribution diagrams of a heat dissipation structure surface, which are obtained by the thermal fluid simulation under a natural convection (no wind) condition of the thermal fluid simulation in the analysis models of FIGS. 16A, 16B, and 16C.

Specifically, FIG. 17A illustrates a result of the heat dissipation structure example with only the general continuous straight fins (fin height: 20 mm), FIG. 17B illustrates a result of the heat dissipation structure example with only the general discrete rectangular fins (fin height: 20 mm), and FIG. 17C illustrates a result of the heat dissipation structure example in which the straight fins (fin height: 15 mm) and the rectangular fins (fin height: 20 mm) of the present disclosure are alternately arranged. As is apparent from comparison between FIGS. 17B and 17C, it can be seen that a high-temperature region is reduced as compared with the case of only the general rectangular fins.

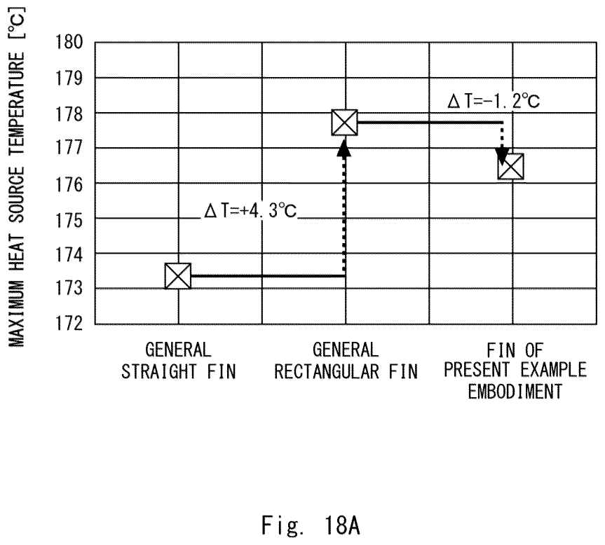

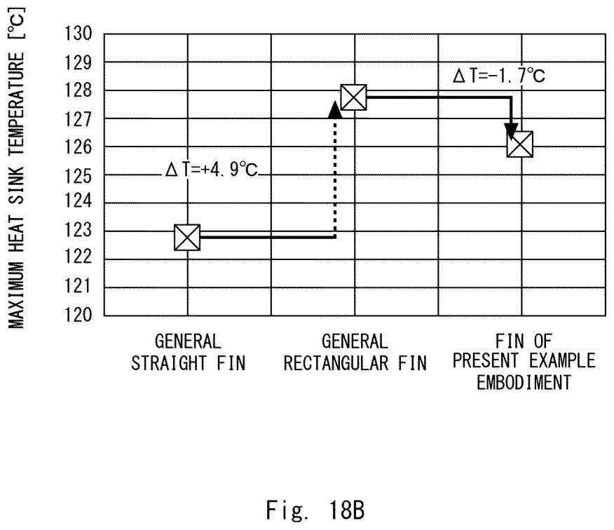

FIGS. 18A and 18B are diagrams illustrating a maximum heat source temperature of the heat dissipation structure surface and a maximum temperature of a heat dissipation structure portion (heat sink), which are obtained by the thermal fluid simulation under the natural convection (no wind) condition of the thermal fluid simulation in the analysis models of FIGS. 16A, 16B, and 16C.

In the radiator of the configuration example of the present disclosure, similarly to the tendency of the decrease in the high-temperature region of the temperature distributions in the entire heat dissipation structures in FIGS. 17A, 17B, and 17C, as illustrated in FIGS. 18A and 18B, as compared with the case of only the general rectangular fins, the temperature decreases and approaches that in the case of the straight fins having large heat dissipation areas.

As described above, the radiator 1 of the present example embodiment can achieve both suppression of radio wave propagation in each direction and improvement of the heat dissipation characteristics. Then, in the radiator 1 of the present example embodiment, the heat dissipation fins themselves effectively function as electromagnetic walls due to the exhibition of the EBG by the heat dissipation fins in the vicinity of an antenna height, and an additional wall for suppressing coupling between antennas and a surface wave becomes unnecessary. Therefore, the radiator 1 of the present example embodiment can improve the degree of freedom in designing the radiator 1.

### Second Example Embodiment

The present example embodiment will be described with reference to FIGS. 19 to 23C. The present example embodiment is an array antenna device 7 that is a representative example of a wireless device in a case where a radiator 1 exemplified in the present disclosure is applied to both polarized antenna elements.

FIG. 19 is a diagram illustrating a Vivaldi antenna element that is applied as an example of an antenna element capable of broadband operation and has an exponential-like metal pattern. An antenna element 11 in FIG. 19 is a representative example of a radiating element, and is the Vivaldi antenna element having excellent broadband characteristics in which metal patterns 12a and 12b are each formed in an exponential shape on a dielectric substrate. An antenna feeder line 13 is connected to the metal pattern 12b.

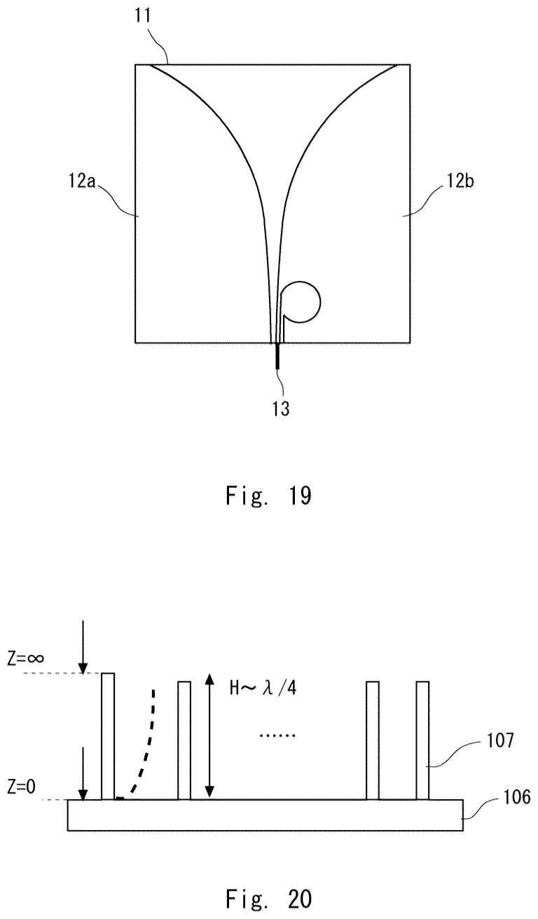

FIG. 20 is a schematic diagram illustrating a surface impedance at a fin end surface of a heat dissipation fin structure having EBG characteristics. As illustrated in FIG. 20, heat dissipation fins 107 disposed on top of a heat dissipation plate 106 have high impedance surfaces having a very high surface impedance in a heat dissipation reflection surface (fin end surface) constituted by heat dissipation fins by impedance conversion, particularly in a case where a fin height of the heat dissipation fins 107 is (1+2N)/4 (here, N is an integer equal to or more than 0) of a wavelength λ of a predetermined frequency.

In the radiator 1 exemplified in the present disclosure, the first heat dissipation fins 3 and the second heat dissipation fins 4 having the fin heights of λ/4 and λ/6 are mixed as illustrated in FIG. 11, but it is presumed that a high impedance surface at a fin end surface similar to that in FIG. 20 is achieved.

At this time, an artificial magnetic conductor (AMC) is generated, and a phase of a reflected wave at the fin end surface exhibits a unique characteristic in which it changes from the 180° reflection phase of a normal conductor to approximately 0°. This characteristic is suitable as a surface in the vicinity of the array antenna device 7 since the reflected wave operates without canceling a desired radio wave around the antenna elements.

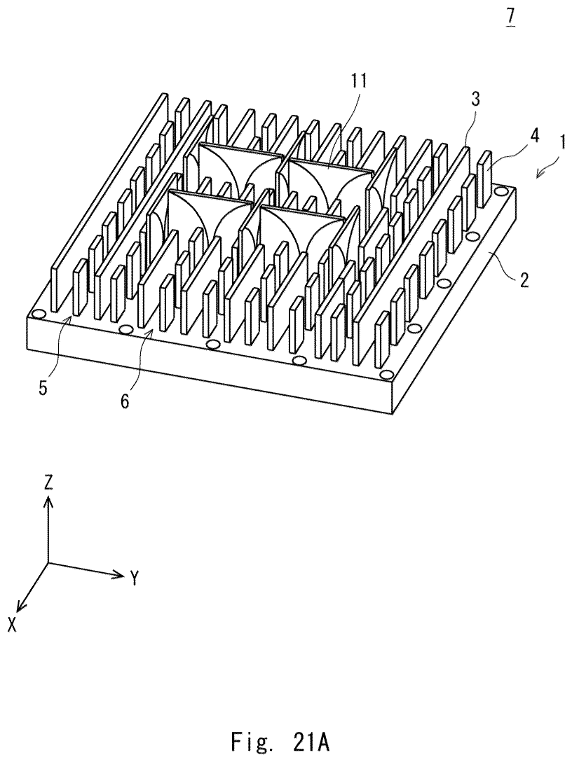

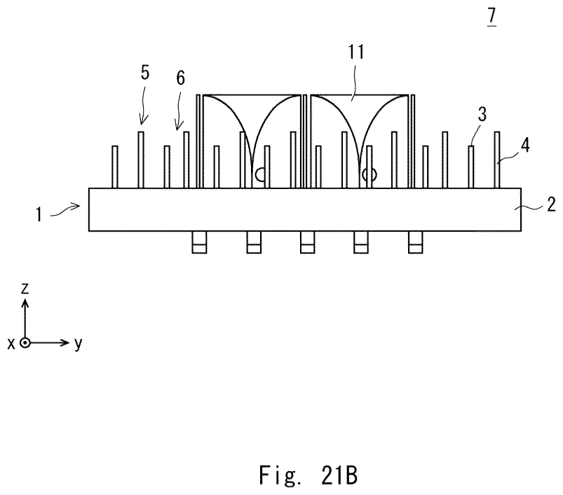

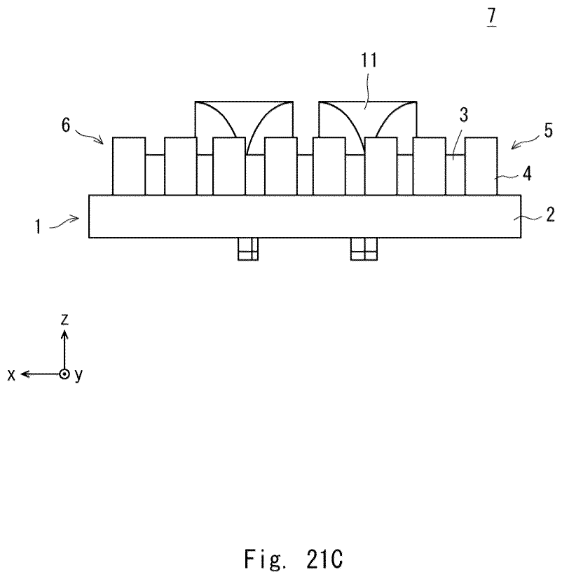

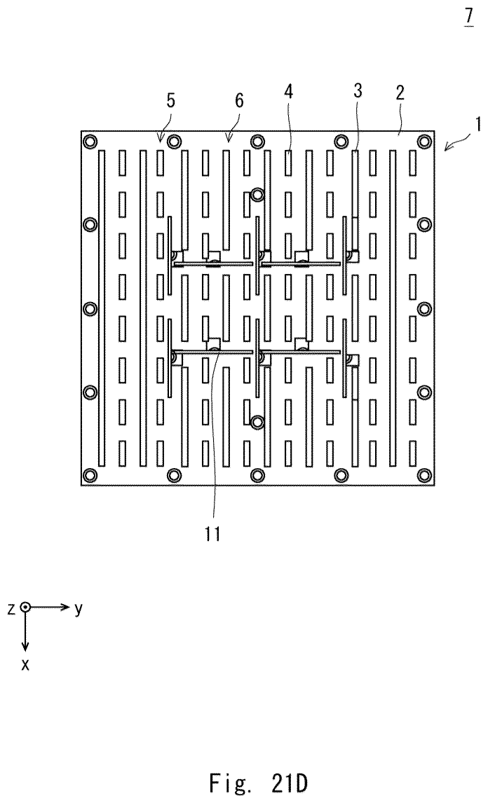

FIGS. 21A, 21B, 21C, and 21D are a perspective view, respective side views from two directions, and a plan view of an electromagnetic field simulation model of an array antenna device (the number of orthogonal polarization elements is 3×2 elements and 2×2 elements) in which the Vivaldi antenna elements are orthogonally arranged in the radiator exemplified in the present disclosure.

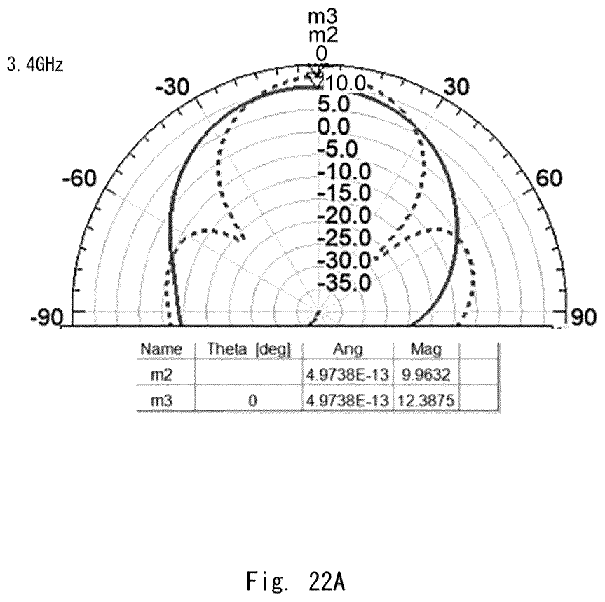

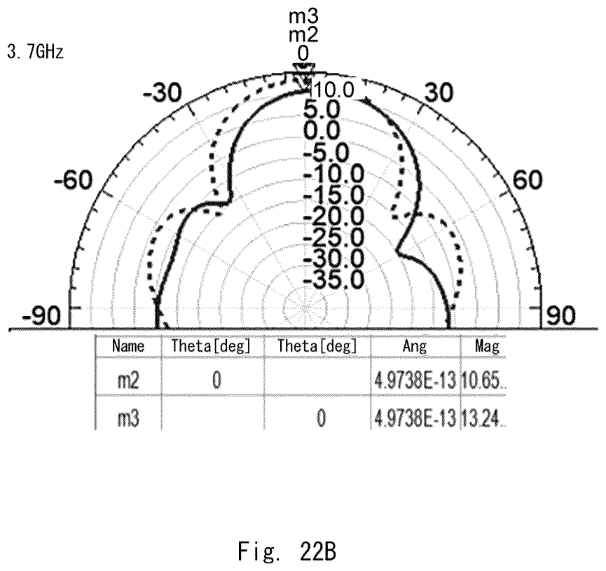

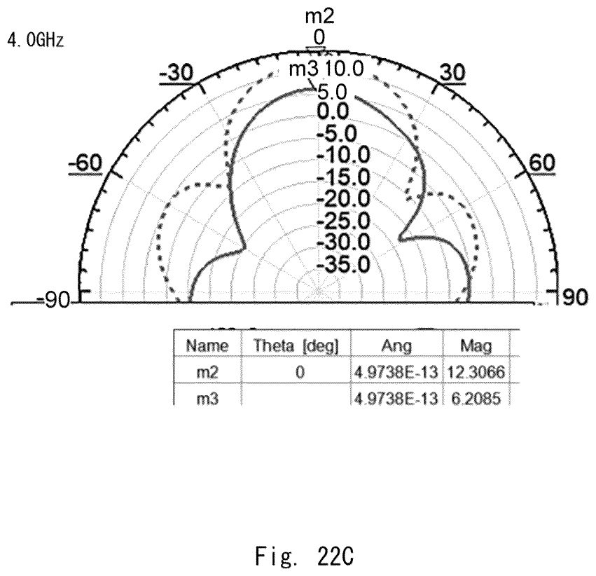

FIGS. 22A, 22B, and 22C are diagrams illustrating simulation results of radiation patterns during operation of the 3×2 array Vivaldi antenna with only a metal surface without general fins (broken line) and a fin height of 20 mm of a continuous fin row (solid line), for comparison of effects of the configuration example of the radiator of the present disclosure.

At any frequency of 3.4 GHz, 3.7 GHz, and 4.0 GHz, the radiation patterns and antenna gain are deteriorated from a case where an ideal reflector without fins is provided.

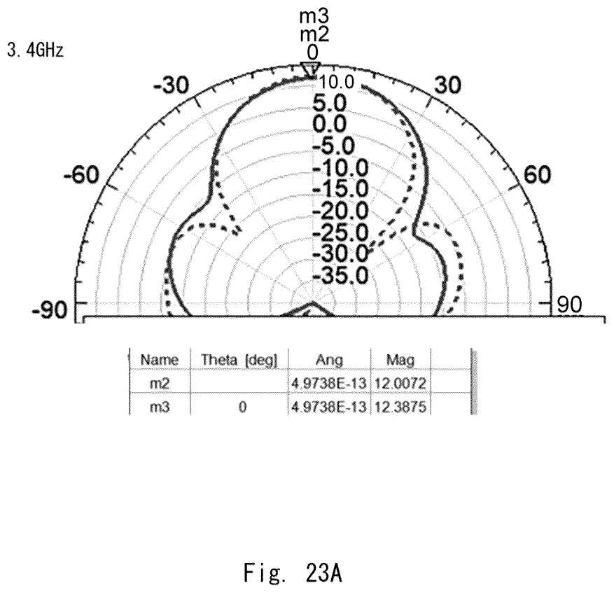

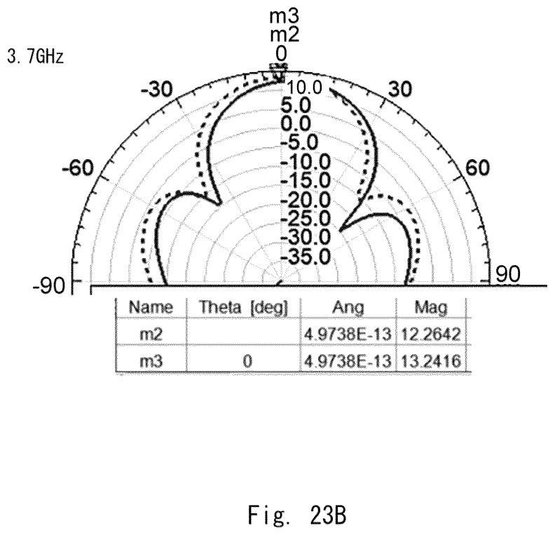

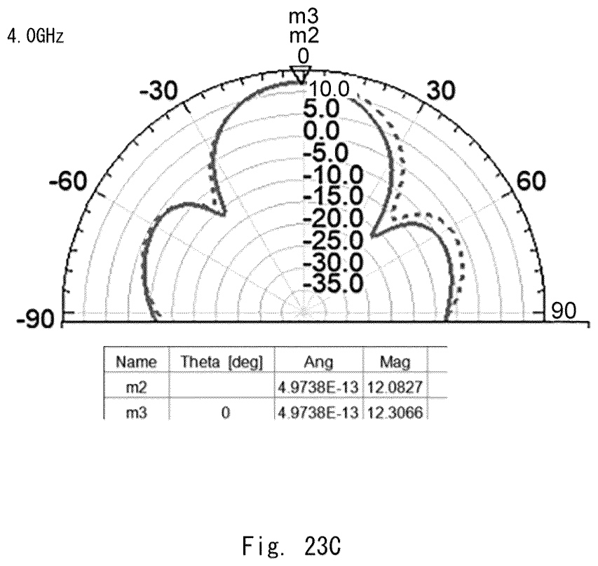

On the other hand, FIGS. 23A, 23B, and 23C are diagrams illustrating simulation results of radiation patterns during operation of the 3×2 array Vivaldi antenna with only the metal surface without general fins (broken line) and according to the present disclosure, that is, with a fin height of 15 mm of a continuous fin row (solid line).

It can be seen that the radiation patterns and the antenna gain are maintained to the same extent as those of the ideal reflector without fins at any frequency of 3.4 GHz, 3.7 GHz, and 4.0 GHz. Similar results are obtained for the orthogonal 2×2 elements.

As described above, dual-polarized antenna characteristics can be maintained in the array antenna device 7 while the heat dissipation characteristics are enhanced by the radiator 1 of the present example embodiment. Here, as illustrated in FIG. 21A and the like, the first heat dissipation fins 3 are divided in the x-axis direction, but it is presumed that desired radio wave propagation can be prevented as long as the first heat dissipation fins 3 have a fin length equivalent to at least two rows of the second heat dissipation fins 4. In the present example embodiment, the configuration example in which the antenna elements 11 are applied to the radiator 1 as a representative example of the radiating elements has been described, but a reflection structure such as a metasurface may be formed by applying reflective elements to the radiator 1.

### Third Example Embodiment

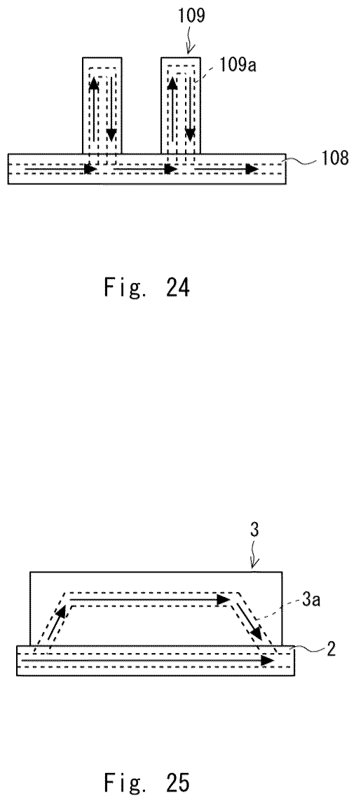

FIG. 24 is a diagram schematically illustrating a flow of a refrigerant in a flow path in a case where the flow path of the refrigerant is provided inside general rectangular heat dissipation fins. FIG. 25 is a diagram schematically illustrating a flow of the refrigerant in a flow path in a case where the flow path of the refrigerant is provided inside a first heat dissipation fin in a configuration example of the present disclosure. In FIGS. 24 and 25, the flows of the refrigerant are indicated by arrows, and the flow paths are indicated by broken lines.

A fin length of the first heat dissipation fin 3 disposed on a heat dissipation plate 2 as illustrated in FIG. 25 is longer than a fin length of the rectangular heat dissipation fins 109 disposed on a heat dissipation plate 108 as illustrated in FIG. 24.

Therefore, as is clear from comparison between FIG. 24 and FIG. 25, as compared with a case where the refrigerant flows in a flow path 109a inside the heat dissipation fins 109, in a case where the refrigerant flows in a flow path 3a inside the first heat dissipation fin 3, a resistance in the flow path is reduced and the flow of the refrigerant is improved, heat exchange between the refrigerant and a heat dissipation structure is efficiently performed, and heat dissipation performance is improved.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with other example embodiments.

For example, in the third example embodiment, the refrigerant flows in the flow path inside the heat dissipation plate 2 and the first heat dissipation fins 3. However, the refrigerant may flow in a flow path inside the second heat dissipation fins 4 as well.

For example, a fin height h1 of the first heat dissipation fin 3 of the above example embodiment is merely an example, and may be equal to or less than λ×(N/2+A×1/5) (where λ is a wavelength corresponding to a predetermined frequency, N is an integer equal to or more than 0, and A is an arbitrary constant).

For example, a fin height h2 of the second heat dissipation fin 4 of the above example embodiment is merely an example, and may be equal to or less than λ×(N/2+A×1/4) (where λ is the wavelength corresponding to the predetermined frequency, N is the integer equal to or more than 0, and A is the arbitrary constant).

Each of the drawings is merely an example to illustrate one or more example embodiments. Each drawing is not associated with only one specific example embodiment, but may be associated with one or more other example embodiments. As those skilled in the art will appreciate, various features described with reference to any one of the drawings may be combined with features illustrated in one or more other drawings, for example, to create an example embodiment that is not explicitly illustrated or described. All of the features illustrated in any one of the drawings for describing the exemplary example embodiments are not necessarily mandatory, and some features may be omitted.

Some or all of the above example embodiments may be described as the following Supplementary Notes, but are not limited to the following.

### Supplementary Note 1

A radiator including:
a heat dissipation plate that supports a heat source;
first heat dissipation fins disposed on the heat dissipation plate and extending in a first direction in a plane of the heat dissipation plate; and
second heat dissipation fins disposed on the heat dissipation plate and extending in the first direction; wherein
the heat dissipation plate, the first heat dissipation fins, and the second heat dissipation fins are made of a solid material having thermal conductivity and electrical conductivity,
a heat dissipation fin structure is formed in which the first heat dissipation fins and the second heat dissipation fins are arranged in a predetermined order in a second direction in the plane of the heat dissipation plate,
a fin length of the second heat dissipation fins in the first direction is shorter than a fin length of the first heat dissipation fins in the first direction, and
a fin height of the first heat dissipation fins is lower than a fin height of the second heat dissipation fins.

### Supplementary Note 2

The radiator according to Supplementary Note 1, wherein the first heat dissipation fins and the second heat dissipation fins are alternately arranged in the second direction.

Supplementary Note 3

The radiator according to Supplementary Note 1 or 2, wherein the first direction and the second direction are orthogonal to each other.

### Supplementary Note 4

The radiator according to any one of Supplementary Notes 1 to 3, wherein the fin height of the first heat dissipation fins and the fin height of the second heat dissipation fins are heights at which the heat dissipation fin structure exhibits an electromagnetic band gap for a predetermined frequency.

### Supplementary Note 5

The radiator according to any one of Supplementary Notes 1 to 4, wherein the fin height of the second heat dissipation fins is λ×(N/2+A×1/4) (where λ is a wavelength corresponding to a predetermined frequency, N is an integer equal to or more than 0, and A is an arbitrary constant).

### Supplementary Note 6

The radiator according to any one of Supplementary Notes 1 to 5, wherein the fin height of the first heat dissipation fins is equal to or less than λ×(N/2+A×1/5) (where λ is a wavelength corresponding to a predetermined frequency, N is an integer equal to or more than 0, and A is an arbitrary constant).

### Supplementary Note 7

The radiator according to any one of Supplementary Notes 1 to 6, wherein a distance between the first heat dissipation fins and the second heat dissipation fins in the second direction is less than the fin height of the first heat dissipation fins.

### Supplementary Note 8

The radiator according to any one of Supplementary Notes 1 to 7, wherein the second heat dissipation fins have a rectangular shape or a rod shape.

### Supplementary Note 9

The radiator according to any one of Supplementary Notes 1 to 8, including a flow path of a refrigerant inside the first heat dissipation fins or the second heat dissipation fins.

### Supplementary Note 10

A wireless device including:
the radiator according to any one of Supplementary Notes 1 to 9; and
a radiating element or a reflective element disposed inside a heat dissipation fin structure of the radiator.

1. A radiator comprising:
a heat dissipation plate that supports a heat source;
first heat dissipation fins disposed on the heat dissipation plate and extending in a first direction in a plane of the heat dissipation plate; and
second heat dissipation fins disposed on the heat dissipation plate and extending in the first direction; wherein
the heat dissipation plate, the first heat dissipation fins, and the second heat dissipation fins are made of a solid material having thermal conductivity and electrical conductivity,
a heat dissipation fin structure is formed in which the first heat dissipation fins and the second heat dissipation fins are arranged in a predetermined order in a second direction in the plane of the heat dissipation plate,
a fin length of the second heat dissipation fins in the first direction is shorter than a fin length of the first heat dissipation fins in the first direction, and
a fin height of the first heat dissipation fins is lower than a fin height of the second heat dissipation fins.

2. The radiator according to claim 1, wherein the first heat dissipation fins and the second heat dissipation fins are alternately arranged in the second direction.

3. The radiator according to claim 2, wherein the first direction and the second direction are orthogonal to each other.

4. The radiator according to claim 2, wherein the fin height of the first heat dissipation fins and the fin height of the second heat dissipation fins are heights at which the heat dissipation fin structure exhibits an electromagnetic band gap for a predetermined frequency.

5. The radiator according to claim 2, wherein the fin height of the second heat dissipation fins is λ×(N/2+A×1/4) (where λ is a wavelength corresponding to a predetermined frequency, N is an integer equal to or more than 0, and A is an arbitrary constant).

6. The radiator according to claim 2, wherein the fin height of the first heat dissipation fins is equal to or less than λ×(N/2+A×1/5) (where λ is a wavelength corresponding to a predetermined frequency, N is an integer equal to or more than 0, and A is an arbitrary constant).

7. The radiator according to claim 2, wherein a distance between the first heat dissipation fins and the second heat dissipation fins in the second direction is less than the fin height of the first heat dissipation fins.

8. The radiator according to claim 2, wherein the second heat dissipation fins have a rectangular shape or a rod shape.

9. The radiator according to claim 2, comprising a flow path of a refrigerant inside the first heat dissipation fins or the second heat dissipation fins.

10. A wireless device comprising:
the radiator according to claim 2; and
a radiating element or a reflective element disposed inside a heat dissipation fin structure of the radiator.
